(19) United States
(12) Patent Application Publication
(10) Pub. No.: US 2010/0304568 A1
(43) Pub. Date: Dec. 2, 2010

(54) PATTERN FORMING METHOD

(76) Inventors: Seiro MIYOSHI, Yokohama-shi (JP); Yasunobu Kai, Yokohama-shi (JP); Kentaro Matsunaga, Kawasaki-shi (JP); Keisuke Kikutani, Fujisawa-shi (JP); Eishi Shiobara, Yokohama-shi (JP); Shinya Takahashi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/752,684

(22) Filed: Apr. 1, 2010

(30) Foreign Application Priority Data
May 27, 2009 (JP) 2009-127887

(51) Int. Cl. H01L 21/302; G03F 7/20

(52) U.S. Cl. 438/694; 430/311; 257/E21.214

(57) ABSTRACT

A pattern forming method includes forming a first photoresist on an underlying region, forming a second photoresist on the first photoresist, the second photoresist having an exposure sensitivity which is different from an exposure sensitivity of the first photoresist, radiating exposure light on the first and second photoresists via a photomask including a first transmissive region and a second transmissive region which cause a phase difference of 180° between transmissive light components passing therethrough, the first transmissive region and the second transmissive region being provided in a manner to neighbor in an irradiation region, and developing the first and second photoresists which have been irradiated with the exposure light, thereby forming a structure includes a first region where the underlying region is exposed, a second region where the first photoresist is exposed and a third region where the first photoresist and the second photoresist are left.

### CROSS-REFERENCE TO RELATED APPLICATIONS

This application is based upon and claims the benefit of priority from prior Japanese Patent Application No. 2009-127887, filed May 27, 2009, the entire contents of which are incorporated herein by reference.

### BACKGROUND

1. Field of the Invention

The present invention relates to a pattern forming method.

2. Description of the Related Art

At present, with the development in integration density and microfabrication of semiconductor devices, there is a demand for lithography processes for realizing finer patterns. Conventionally, a fine pattern is formed on a substrate by performing exposure with use of a photomask having a fine pattern. However, in the case where the dimensions of the fine pattern are on the order of nanometers, that is, less than the wavelength of exposure light, it becomes difficult to form the fine pattern. Thus, in the conventional lithography process, it is difficult to form a sufficiently fine pattern.

As a technique of forming a fine pattern, there has been proposed a method in which two kinds of photoresists having different sensitivities to exposure light are stacked, and the stacked photoresists are exposed with use of a photomask having a light-blocking region, a half-tone region and an opening region (see, e.g. Jpn. Pat. Appln. KOKAI Publication No. 2006-30971). According to this method, three regions are formed: a region where both of the two kinds of photoresists are removed, a region where one of the two kinds of photoresists is removed and the other is left, and a region where both of the two kinds of photoresists are left.

However, it is not easy to form, with high precision, a photomask having the above-described three regions, and it is difficult to precisely form a pattern. This being the case, it cannot be said that a fine pattern can always be formed.

### BRIEF SUMMARY

According to a first aspect of the present invention, there is provided a pattern forming method comprising: forming a first photoresist layer on an underlying region; forming a second photoresist layer on the first photoresist layer, the second photoresist layer having an exposure sensitivity which is different from an exposure sensitivity of the first photoresist layer; radiating exposure light on the first and second photoresist layers via a photomask including a first transmissive region and a second transmissive region which cause a phase difference of 180° between transmissive light components passing therethrough, the first transmissive region and the second transmissive region being provided in a manner to neighbor in an irradiation region; and developing the first and second photoresist layers which have been irradiated with the exposure light, thereby forming a structure comprising a first region where the underlying region is exposed, a second region where the first photoresist layer is exposed and a third region where the first photoresist layer and the second photoresist layer are left.

According to a second aspect of the present invention, there is provided a pattern forming method comprising: forming a first photoresist layer on an underlying region; forming a transparent film on the first photoresist layer; forming a second photoresist layer on the transparent layer, the second photoresist layer having an exposure sensitivity which is different from an exposure sensitivity of the first photoresist layer; radiating exposure light on the first photoresist layer, the transparent film and the second photoresist layer via a photomask including a first transmissive region and a second transmissive region which cause a phase difference of 180° between transmissive light components passing therethrough, the first transmissive region and the second transmissive region being provided in a manner to neighbor in an irradiation region; developing the second photoresist layer which has been irradiated with the exposure light, thereby exposing the transparent film; etching the transparent film by using, as a mask, the second photoresist which has been left after the development, thereby exposing the first photoresist layer; and developing the exposed first photoresist layer, thereby forming a structure comprising a first region where the underlying region is exposed, a second region where the first photoresist layer is exposed and a third region where the first photoresist layer, the transparent film and the second photoresist layer are left.

### BRIEF DESCRIPTION OF THE SEVERAL VIEWS OF THE DRAWING

FIG. 1 schematically illustrates a part of a pattern forming method according to a first embodiment of the present invention;

FIG. 2 schematically illustrates a part of the pattern forming method according to the first embodiment of the invention;

FIG. 3A schematically shows a transmissive light amount distribution of transmissive light which has passed through a photomask, and FIG. 3B three-dimensionally shows the transmissive light amount distribution of FIG. 3A;

FIG. 4 schematically illustrates a part of the pattern forming method according to the first embodiment of the invention;

FIG. 5 schematically illustrates a part of the pattern forming method according to the first embodiment of the invention;

FIG. 6A and FIG. 6B schematically show the structure of a photomask 10;

FIG. 7 schematically illustrates a part of a pattern forming method according to a second embodiment of the present invention;

FIG. 8 schematically illustrates a part of the pattern forming method according to the second embodiment of the invention;

FIG. 9 schematically illustrates a part of the pattern forming method according to the second embodiment of the invention;

FIG. 10 schematically illustrates a part of the pattern forming method according to the second embodiment of the invention;

FIG. 11 schematically illustrates a part of the pattern forming method according to the second embodiment of the invention;

FIG. 12 schematically illustrates a part of the pattern forming method according to the second embodiment of the invention;

FIG. 13 schematically illustrates a part of the pattern forming method according to the second embodiment of the invention;

FIG. 14 schematically illustrates a part of the pattern forming method according to the second embodiment of the invention;

FIG. 15 schematically illustrates a part of the pattern forming method according to the second embodiment of the invention;

FIG. 16 schematically illustrates a part of the pattern forming method according to the second embodiment of the invention;

FIG. 17 schematically illustrates a part of the pattern forming method according to the second embodiment of the invention;

FIG. 18 schematically illustrates a part of a pattern forming method according to a third embodiment of the present invention;

FIG. 19 schematically illustrates a part of the pattern forming method according to the third embodiment of the invention;

Part (a) of FIG. 20 schematically shows the structure of a photomask 30, and part (b) of FIG. 20 shows a light amount distribution of transmissive light which has passed through the photomask of part (a) of FIG. 20, and part (c) of FIG. 20 schematically shows the amounts of light components which have passed through the photomask of part (a) of FIG. 20 and the positions of the light components;

FIG. 21 schematically illustrates a part of the pattern forming method according to the third embodiment of the invention;

FIG. 22 schematically illustrates a part of the pattern forming method according to the third embodiment of the invention;

FIG. 23 schematically illustrates a part of a pattern forming method according to a fourth embodiment of the present invention;

FIG. 24 schematically illustrates a part of the pattern forming method according to the fourth embodiment of the invention;

FIG. 25 schematically illustrates a part of the pattern forming method according to the fourth embodiment of the invention;

FIG. 26 schematically illustrates a part of the pattern forming method according to the fourth embodiment of the invention;

FIG. 27 schematically illustrates a part of the pattern forming method according to the fourth embodiment of the invention;

FIG. 28 schematically illustrates a part of the pattern forming method according to the fourth embodiment of the invention;

FIG. 29 schematically illustrates a part of a pattern forming method according to a fifth embodiment of the present invention;

FIG. 30 schematically illustrates a part of the pattern forming method according to the fifth embodiment of the invention;

FIG. 31 schematically illustrates a part of the pattern forming method according to the fifth embodiment of the invention;

FIG. 32 schematically illustrates a part of the pattern forming method according to the fifth embodiment of the invention;

FIG. 33 schematically illustrates a part of the pattern forming method according to the fifth embodiment of the invention;

FIG. 34 schematically illustrates a part of the pattern forming method according to the fifth embodiment of the invention;

FIG. 35 schematically illustrates a part of the pattern forming method according to the fifth embodiment of the invention;

FIG. 36 schematically illustrates a part of the pattern forming method according to the fifth embodiment of the invention;

FIG. 37 schematically illustrates a part of the pattern forming method according to the fifth embodiment of the invention;

FIG. 38 schematically illustrates a part of the pattern forming method according to the fifth embodiment of the invention;

FIG. 39 schematically illustrates a part of the pattern forming method according to the fifth embodiment of the invention;

FIG. 40 schematically illustrates a part of a pattern forming method according to a sixth embodiment of the present invention;

FIG. 41 schematically illustrates a part of the pattern forming method according to the sixth embodiment of the invention;

FIG. 42 schematically illustrates a part of the pattern forming method according to the sixth embodiment of the invention;

FIG. 43 schematically illustrates a part of the pattern forming method according to the sixth embodiment of the invention;

FIG. 44 schematically illustrates a part of the pattern forming method according to the sixth embodiment of the invention; and

FIG. 45 schematically illustrates a part of the pattern forming method according to the sixth embodiment of the invention.

### DETAILED DESCRIPTION

Embodiments of the present invention will now be described with reference to the accompanying drawings.

### First Embodiment

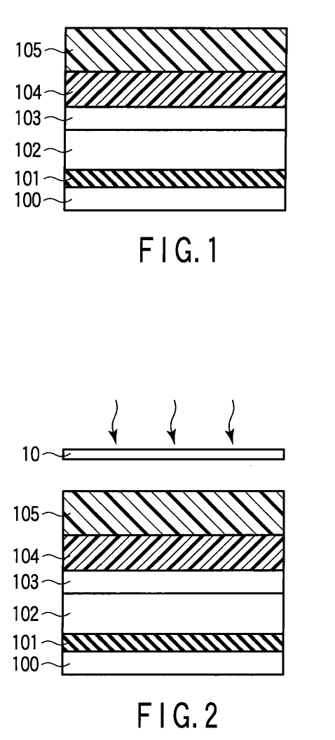

A pattern forming method according to a first embodiment of the invention is described with reference to FIG. 1 through FIG. 6A and FIG. 6B.

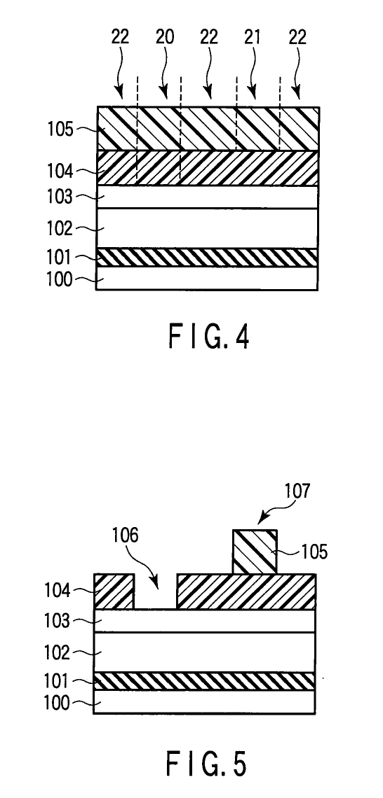

FIG. 1, FIG. 2, FIG. 4 and FIG. 5 schematically illustrate the pattern forming method of the first embodiment.

To begin with, as shown in FIG. 1, a silicon nitride film with a thickness of about 200 nm is formed as a to-be-processed film 101 on a substrate 100. A hard mask material with a thickness of about 200 nm is formed as a lower hard mask layer 102 on the to-be-processed film 101. Further, a hard mask material with a thickness of about 50 nm is formed as an upper hard mask layer (underlying region) 103 on the lower hard mask layer 102. A positive-type photoresist material is coated on the upper hard mask layer 103 and is baked. Thereby, a lower resist layer (first photoresist layer) 104 with a thickness of about 100 nm is formed. A positive-type photoresist material, which has a higher sensitivity (exposure sensitivity) to exposure light than the lower resist layer 104 (i.e. has a lower exposure threshold than the lower resist layer 104), is coated on the lower resist layer 104 and is baked. Thereby, an upper resist layer (second photoresist layer) 105 with a thickness of about 120 nm is formed. In the case where light with a higher intensity than an exposure threshold is radiated on the above-described positive-type photoresist material, this positive-type photoresist material is dissolved by an alkali solution.

The exposure threshold corresponds to a boundary value between the exposure amount at which the photoresist is dissolved by a developing liquid and the exposure amount at which the photoresist is not dissolved. The exposure threshold is set for each of photoresist materials. In the case of using a positive-type photoresist, a region, which is irradiated with exposure light of a light amount greater than the exposure threshold, is dissolved by the developing liquid, and a region, which is irradiated with exposure light of a light amount less than the exposure threshold, is not dissolved by the developing liquid. On the other hand, in the case of using a negative-type photoresist, a region, which is irradiated with exposure light of a light amount greater than the exposure threshold, is not dissolved by the developing liquid, and a region, which is irradiated with exposure light of a light amount less than the exposure threshold, is dissolved by the developing liquid.

Subsequently, as shown in FIG. 2, with use of an exposure device (not shown), ArF light (wavelength: 193.3 nm) is radiated on the upper resist layer 105 and lower resist layer 104 via a photomask 10, thus performing exposure. The photomask 10 will be described later in detail.

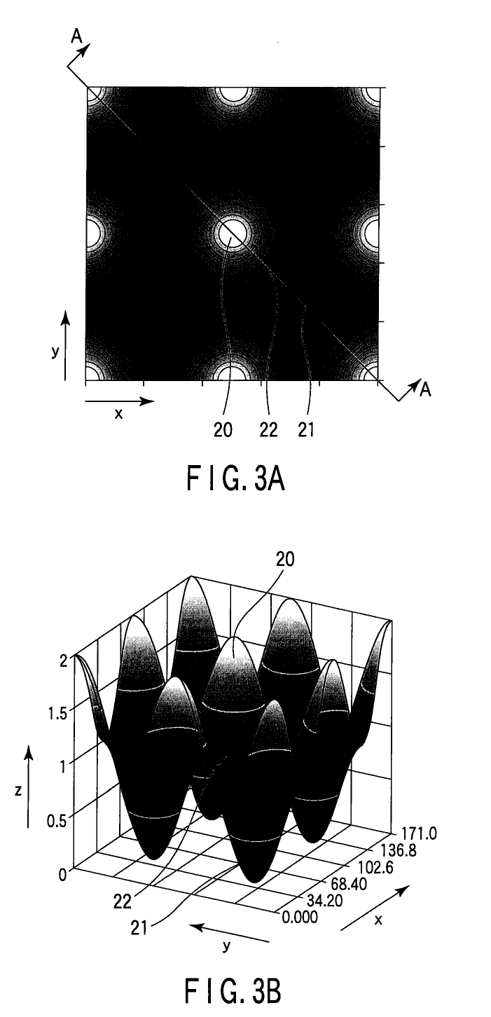

FIG. 3A schematically shows a transmissive light amount distribution of transmissive light which has passed through a photomask. FIG. 3B three-dimensionally shows the transmissive light amount distribution of FIG. 3A. An x-axis and a y-axis are coordinates of transmission positions, and a z-axis indicates the transmissive light amount.

The transmissive light distribution includes a high light amount region 20 (a region of 1.5 or more in the z-axis) where the transmissive light amount is large, a low light amount region 21 (a region of 0.5 or less in the z-axis) where the transmissive light amount is small, and an intermediate light amount region 22 (a region of between 0.5 and 1.5 in the z-axis) where the transmissive light amount is between that of the high light amount region 20 and low light amount region 21. For the purpose of simple description, the three regions, namely, the high light amount region 20, intermediate light amount region 22 and low light amount region 21, are defined in this transmissive light distribution. However, as shown in FIG. 3B, the tree regions are continuous. As regards the transmissive light amount, the light amount is greatest (light intensity is highest) at the central part (apex) of the high light amount region 20, and the light amount is smallest (light intensity is lowest) at the central part (apex) of the low light amount region 21. The pitch between the central parts of a pair of neighboring high light amount regions 20 is about 100 nm.

In the present embodiment, the exposure threshold, at which that part of the upper resist layer 105, which is dissolved by the developing liquid, and that part of the upper resist layer 105, which is not dissolved by the developing liquid, are divided, is z=0.5. With this value being set as a boundary, the intermediate light amount region 22 and the low light amount region 21 are set. The exposure threshold of the lower resist layer 104 is z=1.5, and, with this value being set as a boundary, the intermediate light amount region 22 and the high light amount region 20 are set. The exposure threshold of the lower resist layer 104 is set, with consideration being given to the amount of light that is absorbed by the upper resist layer 105. In the present embodiment, although the two exposure thresholds are set at 0.5 and 1.5, these values may be varied, where necessary.

FIG. 4 illustrates the relationship between the photoresist, on the one hand, and the high light amount region 20, intermediate light amount region 22 and low light amount region 21 in an A-A cross section in FIG. 3A, on the other hand.

Subsequently, as shown in FIG. 5, the upper resist layer 105 and lower resist layer 104 are baked, and the upper resist layer 105 and lower resist layer 104 are developed by using an alkaline developing liquid. Thereby, a hole portion 106 and a pillar portion 107 are formed in the upper resist layer 105 and lower resist layer 104. Specifically, in the lower resist layer 104, only that portion of the resist, which is in the region irradiated with the light of the high light amount region 20 is dissolved, and the hole portion 106 is formed. Since the exposure threshold of the upper resist layer 105 is lower than the exposure threshold of the lower resist layer 104 (the exposure sensitivity of the upper resist layer 105 is higher than the exposure sensitivity of the lower resist layer 104), those portions of the upper resist layer 105, which are irradiated with the light of the high light amount region 20 and intermediate light amount region 22, are dissolved, and the pillar portion 107, which comprises the lower resist layer 104 and upper resist layer 105, is formed at the part corresponding to the low light amount region 21. The diameter of the hole portion 106 is about 35 nm, and the diameter of the pillar portion 107 is about 35 nm. In the fabrication step of FIG. 5, a pattern including the hole portion 106 and pillar portion 107 is formed by single-time development (development using one kind of developing liquid), without changing the developing liquid.

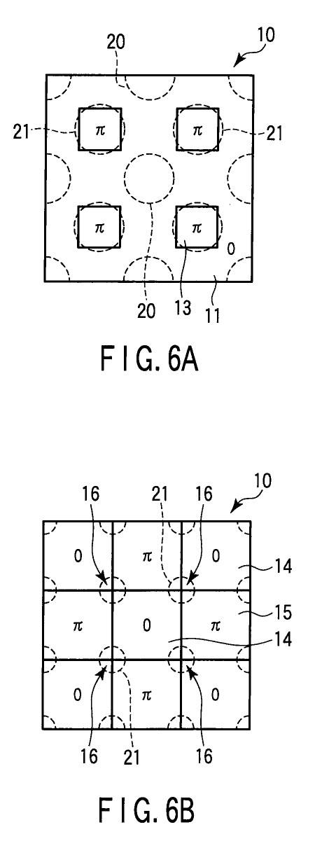

Next, referring to FIG. 6A and FIG. 6B, the structure of the photomask shown in FIG. 2 is described.

FIG. 6A and FIG. 6B schematically show the structure of a transfer pattern of the photomask 10.

In the photomask 10 shown in FIG. 6A, substantially square transmissive regions 13 are provided at regular intervals in a transmissive region 11. To be more specific, the transmissive regions 13 are cyclically disposed in the horizontal direction (first direction) of FIG. 6A and cyclically disposed in the vertical direction (second direction) perpendicular to the horizontal direction, and the transmissive region 11 surrounds the transmissive regions 13. The transmissive region 11 is a non-shifter part (0-part) with a phase difference of 0 degree, and each transmissive region 13 is a shifter part (π-part) with a phase difference of 180 degrees (π). Thereby, the phase difference between the transmissive light passing through the transmissive region 11 and the transmissive light passing through the transmissive regions 13 becomes π. Since the transmissive regions 13 (π-parts) are small and surrounded by the transmissive region (0-part) 11, the transmissive light amount of each transmissive region 13 is decreased by an interference action. Thus, the vicinity of the transmissive region 13 becomes the low light amount region 21. In addition, since an interference action is weak in a region between obliquely neighboring transmissive regions 13, the transmissive light amount in this region is large. Thus, the central part of the region between the obliquely neighboring transmissive regions 13 becomes the high light amount region 20. The other regions become the intermediate light amount regions.

Although the transmissive region 13 has been described above as being substantially square, in the case where the transmissive region 13 is small, the light amount as shown in FIG. 3 can be obtained no matter what shape the transmissive region 13 has. In addition, the transmissive region 11 and the transmissive region 13 may have different transmittances.

In the photomask 10 shown in FIG. 6B, substantially square transmissive regions 14 and substantially square transmissive regions 15 are alternately arranged. To be more specific, the transmissive regions 14 and transmissive regions 15 are cyclically disposed in the horizontal direction (first direction) of FIG. 6B and cyclically disposed in the vertical direction (second direction) perpendicular to the horizontal direction. The transmissive region 14 is a non-shifter part (0-part) with a phase difference of 0 degree, and the transmissive region 15 is a shifter part (π-part) with a phase difference of 180 degrees (π). Thereby, the phase difference between the transmissive light passing through the transmissive region 14 and the transmissive light passing through the transmissive regions 15 becomes π. The transmissive light of the transmissive region 14 and the transmissive light of the transmissive region 15 interfere with each other in a boundary region between the transmissive region 14 and the transmissive region 15, and the light intensity at the boundary region is weakened. In particular, at a central part 16 of four regions, the interference between the transmissive light of the transmissive region 14 and the transmissive light of the transmissive region 15 is strong, and the transmissive light amount is smallest. Thus, the vicinity of the central part 16 becomes the low light amount region 21. In addition, at a central part of each of the transmissive region 14 and transmissive region 15, the interference between the transmissive light of the transmissive region 14 and the transmissive light of the transmissive region 15 is weak, and the transmissive light amount is greatest. Accordingly, the central part of each of the transmissive region 14 and transmissive region 15 becomes the high light amount region 20 (not shown). The other regions become intermediate light amount regions.

In the meantime, the transmissive region 14 and the transmissive region 15 may have different transmittances.

The transmissive light amount distribution, as shown in FIG. 3A and FIG. 3B, can be obtained by any kind of photomask, if the photomask includes the first transmissive region and second transmissive region, which cause a phase difference of 180° between transmissive light components passing therethrough, as shown in FIG. 6A and FIG. 6B, or if the photomask includes the first transmissive region and second transmissive region, which have mutually different transmittances and cause a phase difference of 180° between transmissive light components passing therethrough, the first transmissive region and second transmissive region being provided in a manner to neighbor in the irradiation area.

According to the above-described embodiment, the resist layer with a multi-layer structure is formed by forming two resist layers having different exposure sensitivities. To be more specific, in the case where the two resist layers are of the positive type, the exposure threshold of the lower resist layer 104 is higher than the exposure threshold of the upper resist layer 105. Exposure is performed by using the photomask having two kinds of regions, namely, the non-shifter part and shifter part. Since the transfer pattern of the photomask 10 is formed of only the two kinds of regions that are the non-shifter part and shifter part, the transfer pattern has no complex structure and the photomask can easily be formed. Therefore, according to the present embodiment, the fine resist pattern having the hole portion 106 and pillar portion 107 can exactly be formed by single-time exposure and development with use of the photomask having the simple structure.

### Second Embodiment

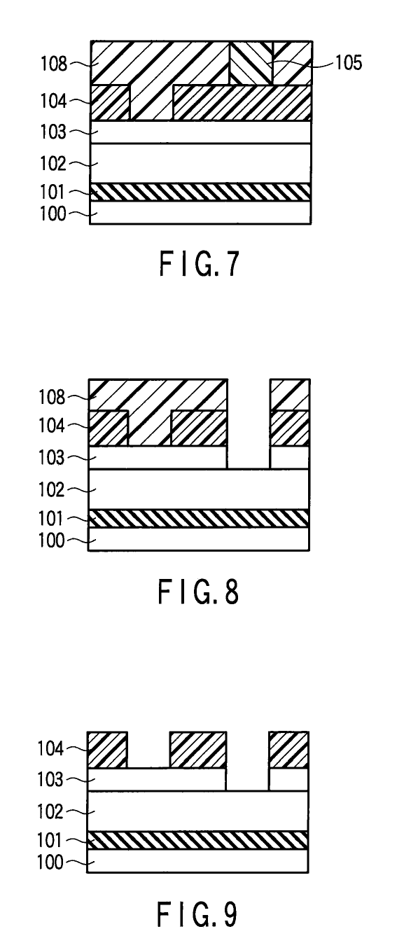

Referring to FIG. 7 to FIG. 17, a pattern forming method according to a second embodiment of the invention is described.

In the above-described first embodiment, a description has been given of the method of forming the resist pattern comprising the lower resist layer 104 and upper resist layer 105. In the second embodiment, a description is given of the method of forming a pattern of a device by using the resist pattern that has been described in the first embodiment.

FIG. 7 to FIG. 17 schematically illustrate the pattern forming method of the present embodiment.

The method of forming the resist pattern having the hole portion 106 and pillar portion 107 shown in FIG. 5 is the same as the method in the first embodiment.

As shown in FIG. 7, a planarization film (e.g. spin-on-glass (SOG)) 108 including silicon is coated on the entire surface of the above-described resist pattern. The planarization film 108 is planarized to a level of the upper part of the upper resist layer 105 by using chemical mechanical polishing (CMP).

Then, as shown in FIG. 8, using the planarization film 108 as a mask, the upper resist layer 105, lower resist layer 104 and upper hard mask layer 103 are etched by using, e.g. a chlorine-based gas. Thereby, a hole pattern is formed in the upper hard mask layer 103 in the region where the pillar portion 107 comprising the lower resist layer 104 and upper resist layer 105 has been formed.

Next, as shown in FIG. 9, the planarization film 108 is removed by wet etching using a fluorine-based solution.

Subsequently, as shown in FIG. 10, using the lower resist layer 104 as a mask, the upper hard mask layer 103 is etched by anisotropic etching such as reactive ion etching (RIE). Thereby, a hole pattern is formed in the upper hard mask layer 103 in the region where the hole portion 106 has been formed.

Thereafter, as shown in FIG. 11, the lower resist layer 104 is removed.

Then, as shown in FIG. 12, using the upper hard mask layer 103 as a mask, the lower hard mask layer 102 is etched by, e.g. RIE.

Subsequently, as shown in FIG. 13, a planarization film 109 including silicon is coated on the entire surface.

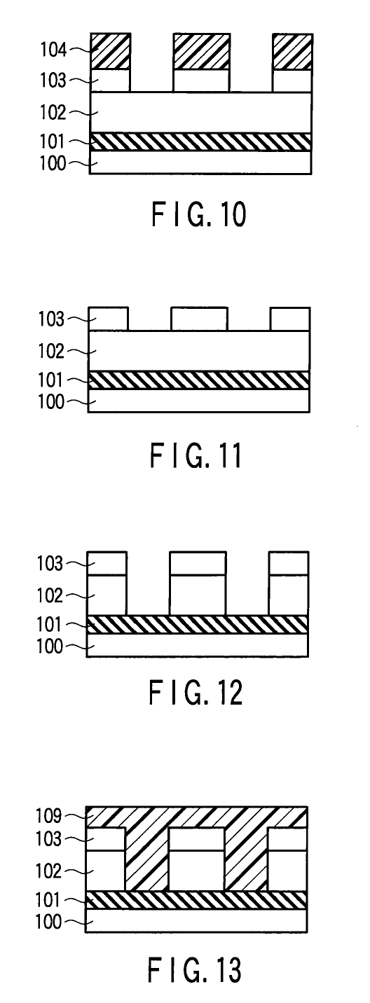

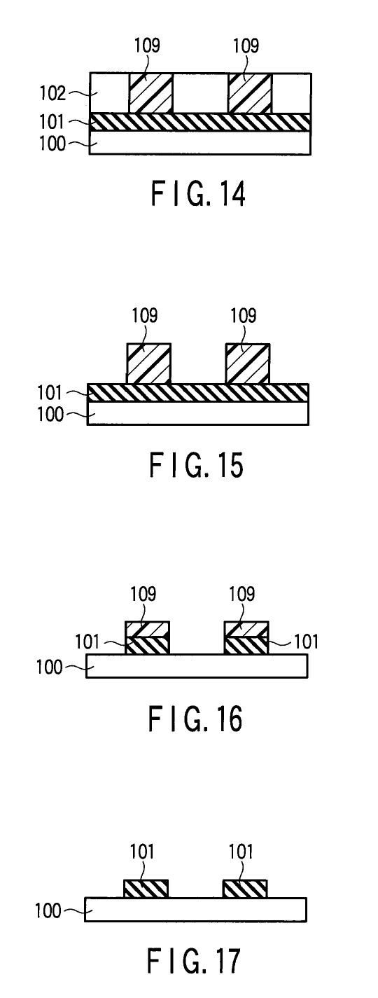

As shown in FIG. 14, the planarization film 109 is planarized by CMP until the lower hard mask layer 102 is exposed, and the planarization film 109 and upper hard mask layer 103 are removed.

Then, as shown in FIG. 15, the lower hard mask layer 102 is removed by ashing using oxygen radicals.

Subsequently, as shown in FIG. 16, using the planarization film 109 as a mask, the to-be-processed film 101 is etched.

Following the above, as shown in FIG. 17, the planarization film 109 is removed by wet etching using a fluorine-based solution. Thus, a pillar pattern of the to-be-processed film 101 can be formed.

According to the above-described second embodiment, the planarization film 108 is formed on the resist pattern of the first embodiment. After the upper resist layer 105 is exposed, only the formation region of the pillar portion 107 is etched by using the planarization film 108 as a mask. Thereby, the hole is formed in the upper hard mask layer 103. Then, the planarization film 108 is removed, and the hole pattern is formed in the upper hard mask layer 103 by using the lower resist layer 104 as a mask. Thereby, the hole can be formed also in the region where the pillar portion 107 is formed. Thus, compared to the case where the hole pattern is formed only in the neighboring low light amount regions 21, as shown in FIG. 3, the pitch of the finally obtained hole pattern can be decreased to 1/1.4 (1/root 2).

In addition, for example, as shown in FIG. 6, since it should suffice if the two kinds of regions which cause a phase difference in transmissive lights thereof are formed in the photomask, the photomask can easily be formed.

Therefore, according to the present embodiment, even by the simple process of forming the photomask, a fine pattern can be formed.

### Third Embodiment

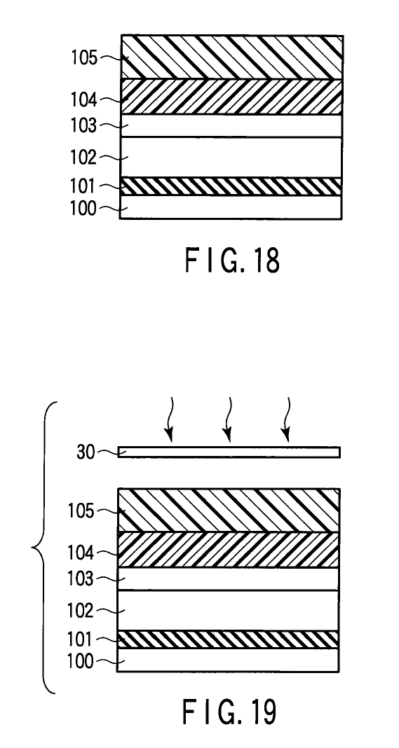

Referring to FIG. 18 to FIG. 22, a pattern forming method according to a third embodiment of the invention is described.

In the above-described first and second embodiments, a description has been given of the method of forming the pillar-and-hole pattern in the photoresist comprising the lower resist layer 104 and upper resist layer 105. In the third embodiment, a method of forming a line-and-space (L/S) pattern is described.

To begin with, as shown in FIG. 18, a silicon nitride film with a thickness of about 200 nm is formed as a to-be-processed film 101 on a substrate 100. A hard mask material with a thickness of about 200 nm is formed as a lower hard mask layer 102 on the to-be-processed film 101. Further, a hard mask material with a thickness of about 50 nm is formed as an upper hard mask layer 103 on the lower hard mask layer 102. A positive-type photoresist material is coated on the upper hard mask layer 103 and is baked. Thereby, a lower resist layer 104 with a thickness of about 100 nm is formed. A positive-type photoresist material, which has a higher exposure sensitivity than the lower resist layer 104 (i.e. has a lower exposure threshold than the lower resist layer 104), is coated on the lower resist layer 104 and is baked. Thereby, an upper resist layer 105 with a thickness of about 120 nm is formed.

Subsequently, as shown in FIG. 19, with use of an exposure device (not shown), ArF light is radiated on the upper resist layer 105 and lower resist layer 104 via a photomask 30, thus performing exposure.

Next, referring to FIG. 20, the structure of the photomask shown in FIG. 19 is described.

Part (a) of FIG. 20 schematically shows the structure of the photomask 30, part (b) of FIG. 20 shows a light amount distribution of transmissive light which has passed through the photomask of part (a) of FIG. 20, and part (c) of FIG. 20 schematically shows the amounts of light components which have passed through the photomask of part (a) of FIG. 20 and the positions of the light components.

As shown in FIG. 20, the photomask 30 has a line-and-space pattern in which transmissive regions 31 and light-blocking regions 32 are cyclically arranged. The cycle (pitch) of the pattern is 100 nm. The light-blocking region 32 may be a region which does not completely block light. As has been described above, since the pitch of lines and spaces is small, the transmissive light amount distribution of the light that has passed through the photomask 30 has a sine-wave shape as shown in part (b) of FIG. 20. In the present embodiment, a region with a light amount greater than E1 is set to be a high light amount region 40, a region with a light amount less than E2 is set to be a low light amount region 41, and a region with a light amount greater than E2 and less than E1 is set to be an intermediate light amount region 42.

The upper resist layer 105 is dissolved with a light amount greater than E2. The lower resist layer 104 is dissolved with a light amount of greater than E1. The exposure threshold of the lower resist layer 104 is set, with consideration being given to the amount of light that is absorbed by the upper resist layer 105.

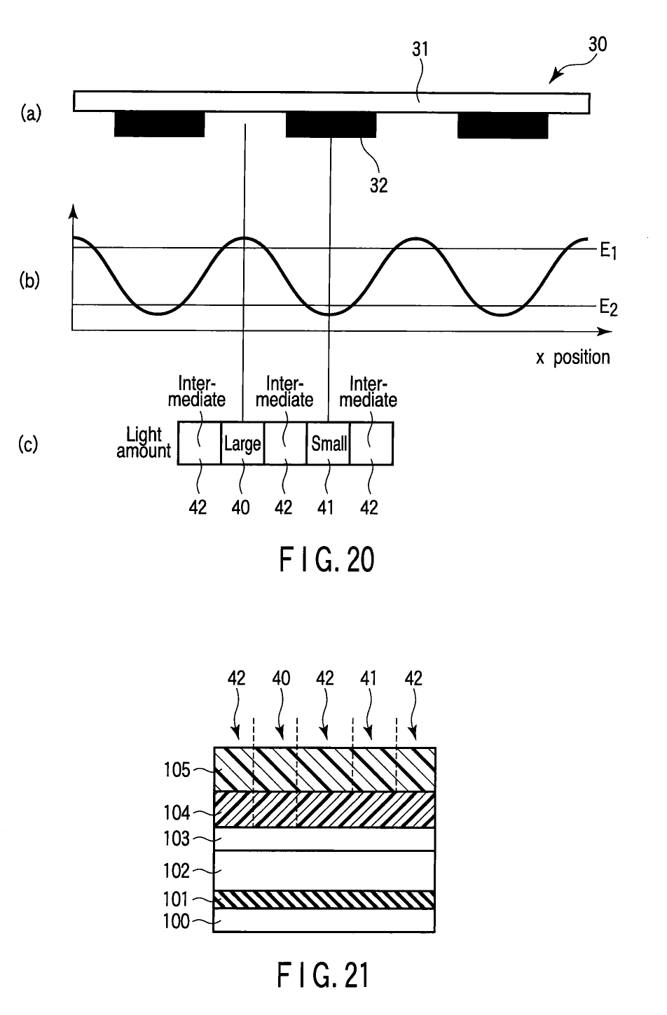

FIG. 21 illustrates the relationship between the photoresist, on the one hand, and the high light amount region 40, low light amount region 41 and intermediate light amount region 42, on the other hand.

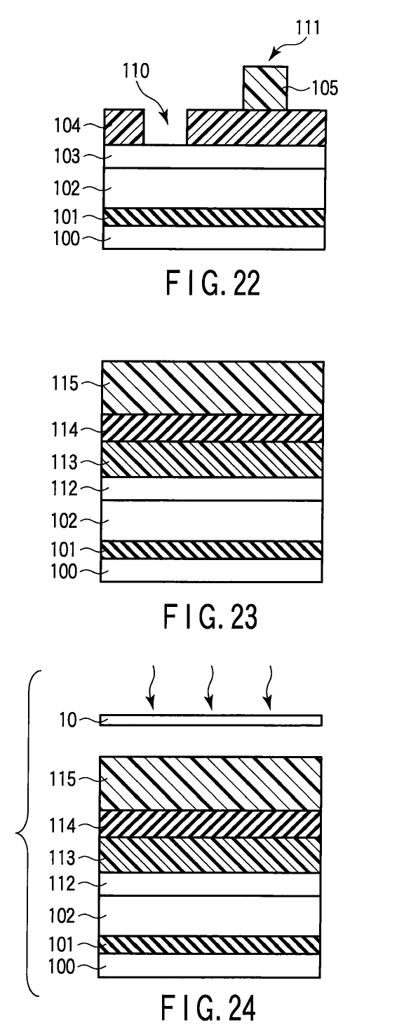

Subsequently, as shown in FIG. 22, the upper resist layer 105 and lower resist layer 104 are baked, and the upper resist layer 105 and lower resist layer 104 are developed by using a developing liquid. Thereby, a trench portion 110 and a projection portion 111 are formed. Specifically, in the lower resist layer 104, only that portion of the resist, which is irradiated with the light of the high light amount region 40, is dissolved, and the trench portion 110 is formed. Since the exposure threshold of the upper resist layer 105 is lower than the exposure threshold of the lower resist layer 104, those portions of the resist, which are irradiated with the light of the high light amount region 40 and intermediate light amount region 42, are dissolved, and the projection portion 111, which comprises the lower resist layer 104 and upper resist layer 105, is formed at the part corresponding to the low light amount region 41. The width of the trench portion 110 is about 25 nm, and the width of the projection portion 111 is about 25 nm.

According to the third embodiment, like the above-described first embodiment, the resist pattern can be formed by single-time exposure and development. Thereby, the pattern can precisely be formed with a smaller number of fabrication steps.

The trench pattern can be formed also in the region where the projection portion 111 has been formed, by the same process as in the above-described second embodiment. Thus, compared to the case where the trench pattern is formed only in the high light amount region 40, as shown in FIG. 20, the pitch of the finally obtained line-and-space pattern can be decreased to ½.

In addition, for example, as shown in FIG. 20, since it should suffice if the two kinds of regions which have different transmittances or the two kinds of regions which have different transmittances and cause a phase difference in transmissive light components passing therethrough are formed in the photomask, the photomask can easily be formed.

Therefore, according to the present embodiment, even by the simple process of forming the photomask, a fine pattern can be formed.

### Fourth Embodiment

Referring to FIG. 23 to FIG. 28, a pattern forming method according to a fourth embodiment of the invention is described.

In the above-described first to third embodiments, a description has been given of the method of forming the pattern of the photoresist comprising the lower resist layer 104 and upper resist layer 105. In the fourth embodiment, a method of forming a pattern comprising a lower resist layer, a transparent film and an upper resist layer is described.

FIG. 23 to FIG. 28 schematically illustrate the pattern forming method of the fourth embodiment.

To begin with, as shown in FIG. 23, a silicon nitride film with a thickness of about 200 nm is formed as a to-be-processed film 101 on a substrate 100. A hard mask material with a thickness of about 200 nm is formed as a lower hard mask layer 102 on the to-be-processed film 101. Further, a hard mask material with a thickness of about 50 nm is formed as an upper hard mask layer 112 on the lower hard mask layer 102. A positive-type photoresist material is coated on the upper hard mask layer 112 and is baked. Thereby, a lower resist layer (first photoresist layer) 113 with a thickness of about 100 nm is formed. An oxide film is coated on the lower resist layer 113, and a transparent film 114 with a thickness of about 50 nm is formed. A positive-type photoresist material, which has a higher exposure sensitivity than the lower resist layer 113, is coated on the transparent film 114 and is baked. Thereby, an upper resist layer (second photoresist layer) 115 with a thickness of about 120 nm is formed.

Subsequently, as shown in FIG. 24, with use of an exposure device (not shown), ArF light is radiated on the upper resist layer 115 and lower resist layer 113 via a photomask 10, thus performing exposure.

As shown in FIG. 3A and FIG. 3B, in the present embodiment, the exposure threshold of the upper resist layer 115 is z=0.5. With this value being set as a boundary, the intermediate light amount region 22 and the low light amount region 21 are set. The exposure threshold of the lower resist layer 113 is z=1.5, and, with this value being set as a boundary, the intermediate light amount region 22 and the high light amount region 20 are set. In addition, the exposure threshold of the lower resist layer 113 is set, with consideration being given to the amount of light that is absorbed by the upper resist layer 115 and transparent film 114.

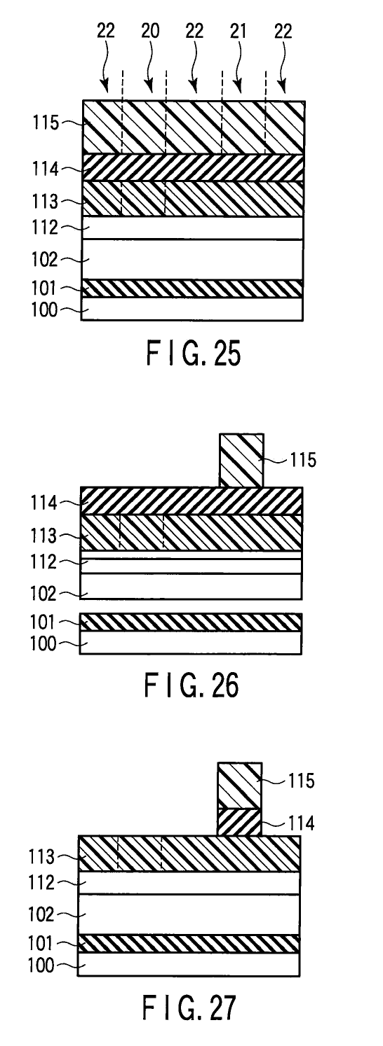

FIG. 25 illustrates the relationship between the photoresist, on the one hand, and the high light amount region 20, intermediate light amount region 22 and low light amount region 21 in the A-A cross section in FIG. 3A, on the other hand.

Subsequently, as shown in FIG. 26, the upper resist layer 115 and lower resist layer 113 are baked, and the upper resist layer 115 is developed by using a developing liquid. Thereby, those portions of the upper resist layer 115, which are irradiated with the light of the high light amount region 20 and intermediate light amount region 22, are dissolved, and that portion of the upper resist layer 115, which is in the low light amount region 21, is left.

Then, as shown in FIG. 27, using the upper resist layer 115 as a mask, the transparent film 114 is etched.

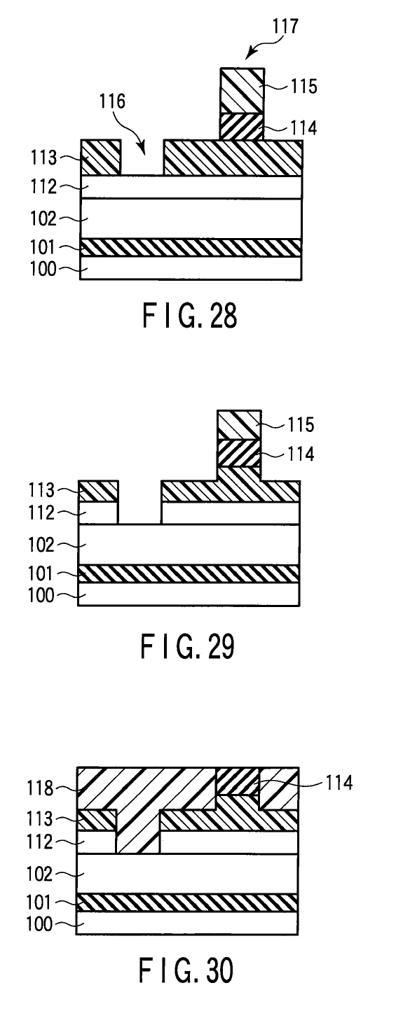

Following the above, as shown in FIG. 28, the lower resist layer 113 is developed by using a developing liquid. Thus, a hole portion 116 and a pillar portion 117 are formed in the upper resist layer 115 and lower resist layer 113. Specifically, only that resist portion of the lower resist layer 113, which is irradiated with the light of the high light amount region 20, is dissolved, and the hole portion 116 is formed. In addition, as described above, the pillar portion 117 comprising the transparent film 114 and upper resist layer 115 is formed. The diameter of the hole portion 116 is about 35 nm, and the diameter of the pillar portion 117 is about 35 nm.

According to the present embodiment, the transparent film is formed between the two resist layers having different exposure thresholds. Thus, the resist layer of the multi-layer structure is formed. To be more specific, in the case where the two resist layers are of the positive type, the exposure threshold of the lower resist layer 113 is higher than the exposure threshold of the upper resist layer 115. Thereby, the resist pattern including the hole portion 116 and pillar portion 117 can be formed by single-time exposure. Hence, the pattern can precisely be formed with a smaller number of fabrication steps.

Furthermore, the transparent film 114 is formed on the lower resist layer 113, and the upper resist layer 115 is formed on the transparent film 114. Accordingly, since the materials of the lower resist layer 113 and the upper resist layer 115 are not mutually affected, the selection of resist materials is easy.

### Fifth Embodiment

Referring to FIG. 29 to FIG. 39, a pattern forming method according to a fifth embodiment of the invention is described.

In the above-described fourth embodiment, a description has been given of the method of forming the pattern comprising the lower resist layer 113, transparent film 114 and upper resist layer 115. In the fifth embodiment, a description is given of the method of forming a pattern of a device by using the photoresist pattern that has been described in the fourth embodiment.

FIG. 29 to FIG. 39 schematically illustrate the pattern forming method of the present embodiment.

The method of forming the resist pattern having the hole portion 116 and pillar portion 117 shown in FIG. 28 is the same as the method in the fourth embodiment.

As shown in FIG. 29, using the hole portion 116 of the lower resist layer 113 as a mask, the upper hard mask layer 112 is etched by, e.g. RIE, and a hole pattern is formed in the upper hard mask layer 112.

Then, as shown in FIG. 30, a planarization film 118 including an organic material is coated on the entire surface of the above-described resist pattern. The planarization film 118 is planarized to a level of the upper part of the transparent film 114 by using CMP.

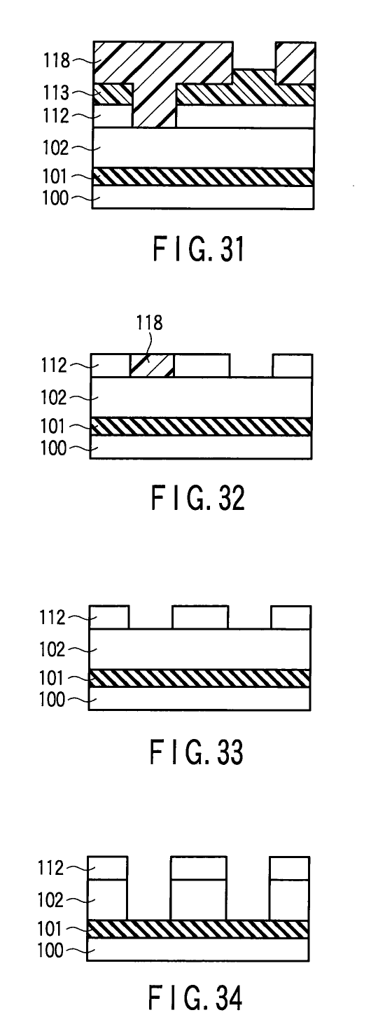

Subsequently, as shown in FIG. 31, the transparent film 114 is removed by wet etching using a fluorine-based solution.

Then, as shown in FIG. 32, the planarization film 118 and lower resist layer 113 are etched by RIE at a uniform rate. At this time, in the formation region of the pillar portion 117, as shown in FIG. 31, the film thickness is small and the upper hard mask layer 112 is also etched. As a result, a hole pattern is formed in the upper hard mask layer 112 which is formed at the pillar portion 117.

Thereafter, as shown in FIG. 33, the planarization film 118 is removed by RIE or by ashing using oxygen radicals.

Using the upper hard mask layer 112 as a mask, as shown in FIG. 34, the lower hard mask layer 102 is etched by, e.g. RIE.

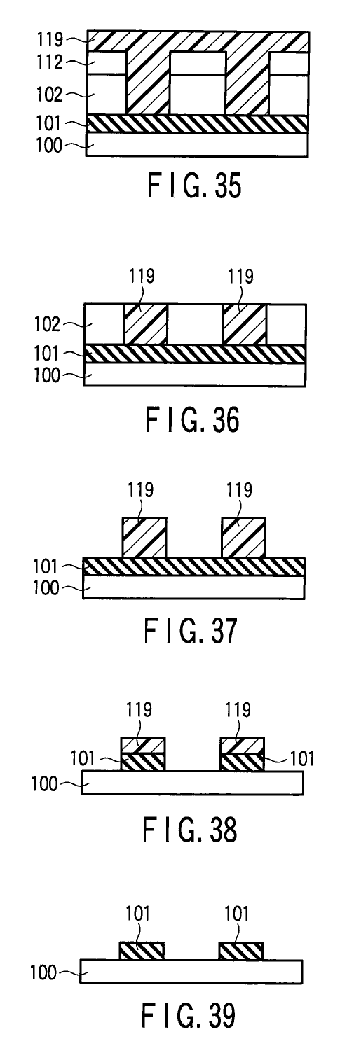

Subsequently, as shown in FIG. 35, a planarization film 119 including silicon is coated on the entire surface.

As shown in FIG. 36, the planarization film 119 is planarized by CMP until the lower hard mask layer 102 is exposed, and the planarization film 119 and upper hard mask layer 112 are removed.

Then, as shown in FIG. 37, the lower hard mask layer 102 is removed by ashing using oxygen radicals.

Subsequently, as shown in FIG. 38, using the planarization film 119 as a mask, the to-be-processed film 101 is etched by, e.g. RIE.

Following the above, as shown in FIG. 39, the planarization film 119 is removed by wet etching using a fluorine-based solution. Thus, a pillar pattern of the to-be-processed film 101 can be formed.

According to the above-described fifth embodiment, the hole is formed in the upper hard mask layer 112 by using the hole portion 116 of the resist pattern of the above-described fourth embodiment. Then, the planarization film 118 is formed on the resist pattern, and the transparent film 114 is exposed. Subsequently, the transparent film 114 is removed, and the planarization film 118, lower resist layer 113 and upper hard mask layer 112 are etched at a uniform rate. Thus, the hole is formed in the upper hard mask layer 112. Thereby, the hole can be formed also in the region where the pillar portion 117 is formed. Thus, compared to the case where the hole pattern is formed only in the neighboring low light amount regions 21, as shown in FIG. 3, the pitch of the finally obtained hole pattern can be decreased to 1/1.4.

In addition, like the above-described second embodiment, for example, as shown in FIG. 6, since it should suffice if the two kinds of regions which cause a phase difference between transmissive light components passing therethrough are formed in the photomask, the photomask can easily be formed.

Therefore, according to the present embodiment, even by the simple process of forming the photomask, a fine pattern can be formed.

### Sixth Embodiment

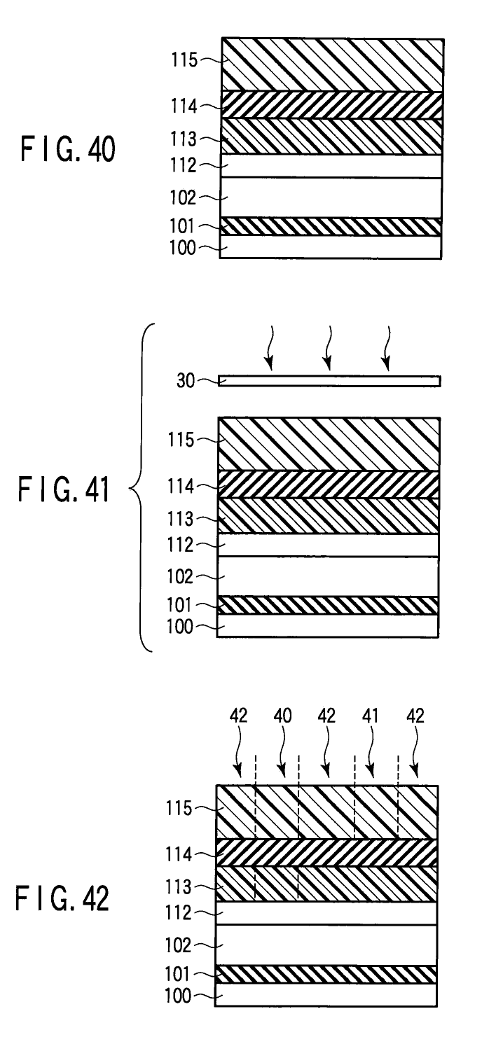

Referring to FIG. 40 to FIG. 45, a pattern forming method according to a sixth embodiment of the invention is described.

In the above-described fourth and fifth embodiments, a description has been given of the method of forming the pillar-and-hole pattern in the photoresist comprising the lower resist layer 113, transparent film 114 and upper resist layer 115. In the sixth embodiment, a method of forming a line-and-space pattern is described.

To begin with, as shown in FIG. 40, a silicon nitride film with a thickness of about 200 nm is formed as a to-be-processed film 101 on a substrate 100. A hard mask material with a thickness of about 200 nm is formed as a lower hard mask layer 102 on the to-be-processed film 101. Further, a hard mask material with a thickness of about 50 nm is formed as an upper hard mask layer 112 on the lower hard mask layer 102. A positive-type photoresist material is coated on the upper hard mask layer 112 and is baked. Thereby, a lower resist layer 113 with a thickness of about 100 nm is formed. An oxide film is coated on the lower resist layer 113, and a transparent film 114 with a thickness of about 50 nm is formed. A positive-type photoresist material, which has a higher exposure sensitivity than the lower resist layer 113, is coated on the transparent film 114 and is baked. Thereby, an upper resist layer (second photoresist layer) 115 with a thickness of about 120 nm is formed.

Subsequently, as shown in FIG. 41, with use of an exposure device, ArF light is radiated on the upper resist layer 115 and lower resist layer 113 via a photomask 30, thus performing exposure.

The upper resist layer 115 is dissolved with a light amount greater than E2 shown in FIG. 20. The lower resist layer 113 is dissolved with a light amount greater than E1. The exposure threshold of the lower resist layer 113 is set, with consideration being given to the amount of light that is absorbed by the upper resist layer 115 and transparent film 114.

FIG. 42 illustrates the relationship between the photoresist, on the one hand, and the high light amount region 40, low light amount region 41 and intermediate light amount region 42, on the other hand.

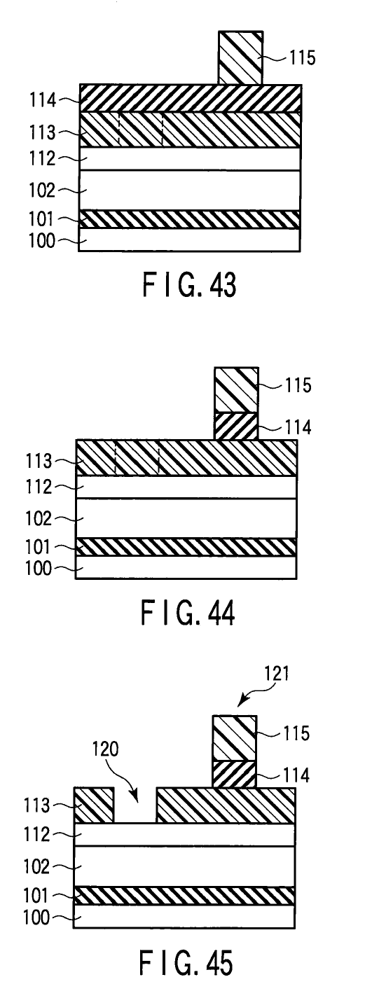

Subsequently, as shown in FIG. 43, the upper resist layer 115 and lower resist layer 113 are baked, and the upper resist layer 115 is developed by using a developing liquid. Thereby, those irradiated regions of the upper resist layer 115, which are in the high light amount region 40 and intermediate light amount region 42, are dissolved, and the irradiated region of the upper resist layer 115, which is in the low light amount region 41, is left.

Then, as shown in FIG. 44, using the upper resist layer 115 as a mask, the transparent film 114 is etched.

Following the above, as shown in FIG. 45, development is performed by using a developing liquid, and a trench portion 120 and a projection portion 121 are formed. Specifically, in the lower resist layer 113, only that portion of the resist, which is irradiated with the light of the high light amount region 40, is dissolved, and the trench portion 120 is formed. In addition, as described above, the projection portion 121, which comprises the transparent film 114 and upper resist layer 115, is formed. The width of the trench portion 120 is about 25 nm, and the width of the projection portion 121 is about 25 nm.

According to the sixth embodiment, like the above-described fourth embodiment, the resist pattern can be formed by single-time exposure. Thereby, the pattern can precisely be formed with a smaller number of fabrication steps.

The trench pattern can be formed also in the region where the projection portion 111 has been formed, by the same process as in the above-described fifth embodiment. Thus, compared to the case where the trench pattern is formed only in the high light amount region 40, as shown in FIG. 20, the pitch of the finally obtained line-and-space pattern can be decreased to ½.

In addition, for example, as shown in FIG. 20, since it should suffice if the two kinds of regions which have different transmittances or the two kinds of regions which have different transmittances and cause a phase difference between transmissive light components passing therethrough are formed in the photomask, the photomask can easily be formed.

Therefore, according to the present embodiment, even by the simple process of forming the photomask, a fine pattern can be formed.

In each of the above-described embodiments, the positive-type resists have been used as the lower resist layer and upper resist layer. The exposure threshold of the lower resist layer has been set, for example, at the exposure amount in the neighborhood of the boundary between the high light amount region 20 and intermediate light amount region 22 shown in FIG. 3A and FIG. 3B, and the exposure threshold of the upper resist layer has been set at the exposure amount in the neighborhood of the boundary between the low light amount region 21 and intermediate light amount region 22 shown in FIG. 3A and FIG. 3B. Alternatively, a negative-type resist (a region irradiated with light having a higher intensity than an exposure threshold is not dissolved by a developing liquid) may be used as the lower resist layer and upper resist layer. In this case, the exposure threshold of the lower resist layer is set at the exposure amount in the neighborhood of the boundary between the low light amount region 21 and intermediate light amount region 22 shown in FIG. 3A and FIG. 3B, and the exposure threshold of the upper resist layer is set at the exposure amount in the neighborhood of the boundary between the high light amount region 20 and intermediate light amount region 22 shown in FIG. 3A and FIG. 3B. The same applies to the case of the line-and-space pattern shown in FIG. 20.

Besides, in each of the above-described embodiments, the silicon nitride film is used as the to-be-processed film 101. However, any kind of material, which functions as the to-be-processed film, may be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming method comprising:
forming a first photoresist layer on an underlying region;
forming a second photoresist layer on the first photoresist layer, the second photoresist layer having an exposure sensitivity which is different from an exposure sensitivity of the first photoresist layer;
radiating exposure light on the first and second photoresist layers via a photomask including a first transmissive region and a second transmissive region which cause a phase difference of 180° between transmissive light components passing therethrough, the first transmissive region and the second transmissive region being provided in a manner to neighbor in an irradiation region; and
developing the first and second photoresist layers which have been irradiated with the exposure light, thereby forming a structure comprising a first region where the underlying region is exposed, a second region where an upper surface of the first photoresist layer is exposed and a third region where a stacked structure comprising the first photoresist layer and the second photoresist layer is left.

2. The method of claim 1, further comprising:
forming a first film on the exposed underlying region and the exposed first photoresist layer;
etching, with use of the first film as a mask, the second photoresist layer of the third region, the first photoresist layer of the third region and the underlying region under the first photoresist layer of the third region;
removing the first film and exposing the first photoresist layer; and
etching the underlying region by using the exposed first photoresist layer as a mask.

3. The method of claim 1, wherein the first transmissive region is periodically disposed in a first direction and periodically disposed in a second direction perpendicular to the first direction, and the second transmissive region surrounds at least of a portion of the first transmissive region.

4. The method of claim 1, wherein the first transmissive region and the second transmissive region are alternately and periodically disposed in a first direction, and are alternately and periodically disposed in a second direction perpendicular to the first direction.

5. The method of claim 1, wherein the first transmissive region and the second transmissive region have different transmittances.

6. The method of claim 1, wherein the first and second photoresist layers are positive-type photoresist layers.

7. The method of claim 6, wherein the exposure sensitivity of the second photoresist layer is higher than the exposure sensitivity of the first photoresist layer.

8. The method of claim 1, wherein the first and second photoresist layers are negative-type photoresist layers.

9. The method of claim 8, wherein the exposure sensitivity of the second photoresist layer is lower than the exposure sensitivity of the first photoresist layer.

10. A pattern forming method comprising:
forming a first photoresist layer on an underlying region;
forming a transparent film on the first photoresist layer;
forming a second photoresist layer on the transparent layer, the second photoresist layer having an exposure sensitivity which is different from an exposure sensitivity of the first photoresist layer;
radiating exposure light on the first photoresist layer, the transparent film and the second photoresist layer via a photomask including a first transmissive region and a second transmissive region which cause a phase difference of 180° between transmissive light components passing therethrough, the first transmissive region and the second transmissive region being provided in a manner to neighbor in an irradiation region;
developing the second photoresist layer which has been irradiated with the exposure light, thereby exposing the transparent film;
etching the transparent film by using, as a mask, the second photoresist which has been left after the development, thereby exposing the first photoresist layer; and
developing the exposed first photoresist layer, thereby forming a structure comprising a first region where the underlying region is exposed, a second region where an upper surface of the first photoresist layer is exposed and a third region where a stacked structure comprising the first photoresist layer, the transparent film and the second photoresist layer are left.

11. The method of claim 10, further comprising:
etching the exposed underlying region by using the exposed first photoresist layer as a mask, thereby forming a first recess in the underlying region;
forming a first film on the first recess portion, the first photoresist layer and the second photoresist layer;
planarizing the first film by performing etching until the transparent film, which is left in the third region, is exposed;
etching the exposed transparent film;
etching the planarized first film, the first photoresist layer and the underlying region, thereby forming a second recess portion in the underlying region and leaving the first film in the first recess portion; and
removing the first film which is left in the first recess portion.

12. The method of claim 10, wherein the first transmissive region is periodically disposed in a first direction and periodically disposed in a second direction perpendicular to the first direction, and the second transmissive region surrounds at least of a portion of the first transmissive region.

13. The method of claim 10, wherein the first transmissive region and the second transmissive region are alternately and periodically disposed in a first direction, and are alternately and periodically disposed in a second direction perpendicular to the first direction.

14. The method of claim 10, wherein the first transmissive region and the second transmissive region have different transmittances.

15. The method of claim 10, wherein the first and second photoresist layers are positive-type photoresist layers.

16. The method of claim 15, wherein the exposure sensitivity of the second photoresist layer is higher than the exposure sensitivity of the first photoresist layer.

17. The method of claim 10, wherein the first and second photoresist layers are negative-type photoresist layers.

18. The method of claim 17, wherein the exposure sensitivity of the second photoresist layer is lower than the exposure sensitivity of the first photoresist layer.
